(19) United States
(12) Patent Application Publication
(10) Pub. No.: US 2025/0212349 A1
(43) Pub. Date: Jun. 26, 2025

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventor: Yuzeng LIU, Osaka (JP)

(73) Assignees: KABUSHIKI KAISHA TOSHIBA, Tokyo (JP); Toshiba Electronic Devices & Storage Corporation, Tokyo (JP)

(21) Appl. No.: 19/076,008

(22) Filed: Mar. 11, 2025

Related U.S. Application Data
(63) Continuation of application No. PCT/JP2024/006787, filed on Feb. 26, 2024.

(30) Foreign Application Priority Data
Jul. 14, 2023 (JP) 2023-115910

(51) Int. Cl. H05K 5/04; H01L 23/051; H05K 5/03

(52) U.S. Cl. CPC H05K 5/04; H01L 23/051; H05K 5/03

(57) ABSTRACT

According to one embodiment, a semiconductor device includes a housing including a side wall surrounding an opening, and a receiving part protruding from the side wall; and a cover including an engaging part fitted to the receiving part, and covering a portion of the opening, wherein the engaging part includes an extending portion and a pair of engaging claws protruding from the extending portion, each of the engaging claws has a first engaging surface inclined with respect to a first direction, the receiving part includes a protruding portions including a protruding surface inclined with respect to the first direction, and a lower side of the first engaging surface and a lower side of the protruding surface are inclined so as to become higher toward the side wall.

### CROSS-REFERENCE TO RELATED APPLICATIONS

This application is a Continuation Application of PCT Application No. PCT/JP2024/006787, filed Feb. 26, 2024 and based upon and claiming the benefit of priority from Japanese Patent Application No. 2023-115910, filed Jul. 14, 2023, the entire contents of all of which are incorporated herein by reference.

### FIELD

Embodiments described herein relate generally to a semiconductor device.

### BACKGROUND

As a semiconductor device, a semiconductor module including a housing in which an electronic component is housed and a cover of the housing is known. In such a semiconductor device, the electronic component disposed in the housing is protected.

### BRIEF DESCRIPTION OF THE DRAWINGS

FIG. 1 is a perspective view for explaining an example of a structure of a semiconductor device according to an embodiment.

FIG. 2 is a perspective view for explaining an example of the structure of the semiconductor device according to the embodiment.

FIG. 3 is a perspective view for explaining examples of structures of a receiving part and engaging part of the semiconductor device according to the embodiment.

FIG. 4 is a plan view illustrating an example of a structure of the receiving part of the semiconductor device according to the embodiment as viewed from an X direction.

FIG. 5 is a plan view illustrating an example of a structure of a portion included in the receiving part of the semiconductor device according to the embodiment as viewed from a Y direction.

FIG. 6 is a plan view illustrating an example of a structure of the engaging part of the semiconductor device according to the embodiment as viewed from the X direction.

FIG. 7 is a plan view illustrating an example of a structure of the engaging part of the semiconductor device according to the embodiment as viewed from the Y direction.

FIG. 8 is a perspective view for explaining examples of the structures of the receiving part and engaging part of the semiconductor device according to the embodiment.

FIG. 9 is a perspective view illustrating an example of a structure of an engaging part of a semiconductor device according to a modification as viewed from the X direction.

FIG. 10 is a plan view illustrating an example of a structure of the engaging part of the semiconductor device according to the modification as viewed from the Y direction.

### DETAILED DESCRIPTION

In general, according to one embodiment, a semiconductor device includes a housing including a side wall surrounding an opening for housing an electronic component, and a receiving part provided so as to protrude from the side wall toward the opening; and a cover including an engaging part extending in a first direction and fitted to the receiving part, and covering at least a portion of the opening, wherein the engaging part includes an extending portion extending in the first direction and a pair of engaging claws protruding from the extending portion to each of one end side and another end side in a second direction orthogonal to the first direction at a lower end of the extending portion, each of the engaging claws has a first engaging surface that is continuous with a side surface of the extending portion intersecting the first direction and inclined with respect to the first direction, the receiving part includes a pair of protruding portions including a protruding surface provided so as to face each of the first engaging surfaces and inclined with respect to the first direction, and a lower side of the first engaging surface and a lower side of the protruding surface are inclined so as to become higher toward the side wall in a third direction orthogonal to the first direction and the second direction.

The embodiment will be described below with reference to the drawings. In the following explanation, components having the same functions and structures will be referred to by the same reference symbols. In addition, dimensions and ratios of the drawings are not necessarily the same as actual ones.

### 1. Embodiment

A semiconductor device according to the embodiment will be described.

The semiconductor device according to the embodiment is, for example, a semiconductor module including an electronic component. More specifically, the semiconductor device according to the embodiment is, for example, a power module semiconductor device including a power semiconductor element.

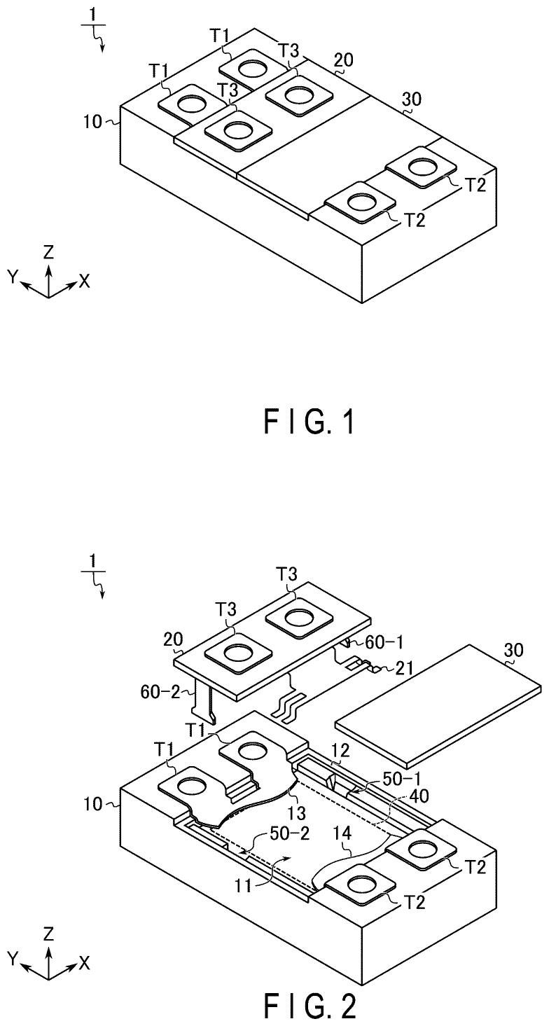

An example of an overall structure of the semiconductor device according to the embodiment will be described with reference to FIG. 1. FIG. 1 is a perspective view for explaining an example of the structure of the semiconductor device according to the embodiment.

In the following description, a Z direction corresponds to, for example, a direction perpendicular to a surface on a side of the semiconductor device on which a cover is provided. An X direction is a direction parallel to the surface. The Y direction is a direction parallel to the surface and perpendicular to the X direction.

The semiconductor device 1 includes a housing 10, covers 20 and 30, and terminals T1, T2, and T3. In the following description, a side of the semiconductor device 1 on which the covers 20 and 30 are provided, out of two sides, the side on which the covers 20 and 30 are provided and a side covered by the housing, is referred to as an upper side. In addition, the side covered by the housing, out of the two sides, the side on which the covers 20 and 30 are provided and the side covered by the housing, is referred to as a lower side.

The housing 10 protects, for example, the electronic component included in the semiconductor device 1 on a side surface and the lower surface. The housing 10 contains, for example, a synthetic resin. The housing 10 is provided with, for example, terminals T1 and T2. Each of the terminals T1 and T2 has, for example, a screw hole through which a connection terminal and a bus bar can be screwed. The terminals T1 and T2 are supplied with, for example, power and a signal for driving the semiconductor device 1 from the outside of the semiconductor device 1. Note that, although the example according to the embodiment illustrates an example in which the two types of terminals T1 and T2 are provided in the housing 10, the present invention is not limited thereto. The type of the terminal provided in the housing 10 may be 0, 1, or 3 or more types. In addition, in the following description, the terminal T1 side out of two sides, terminal T1 and T2 sides, is referred to as one end side in the Y direction. Furthermore, the terminal T2 side out of the two sides, the terminal T1 and T2 sides, is referred to as the other end side in the Y direction.

The covers 20 and 30 are provided, for example, so as to cover at least a part of an upper surface of the housing 10. The covers 20 and 30 are provided, for example, so as to be arranged in the Y direction. The covers 20 and 30 contain, for example, a synthetic resin.

The cover 20 is provided with, for example, a terminal T3. A structure of the terminal T3 is the same as the structures of the terminals T1 and T2. Similar to the terminals T1 and T2, the terminal T3 is supplied with, for example, power and a signal for driving the semiconductor device 1 from the outside of the semiconductor device 1. Note that, although the example according to the embodiment illustrates an example in which the cover 20 is provided with the terminal T3 and the cover 30 is not provided with the terminal, the present invention is not limited thereto. Each of the covers 20 and 30 may be provided with the terminal or may not be provided with the terminal.

An example of the overall structure of the semiconductor device according to the embodiment will be continuously described with reference to FIG. 2. FIG. 2 is a perspective view for explaining an example of the structure of the semiconductor device according to the embodiment. FIG. 2 illustrates the semiconductor device 1 in a state where the covers 20 and 30 are removed.

The housing 10 further includes a side wall 12. The housing 10 is provided with an opening 11 formed so as to be surrounded by the side wall 12 and having an open upper portion. A semiconductor part 40 on which a plurality of semiconductor elements are mounted is housed in the opening 11. The housing 10 further includes receiving parts 50-1 and 50-2 provided so as to protrude from the side wall 12 and used for fixing the cover 20. In the following description, when the receiving parts 50-1 and 50-2 are not distinguished from each other, each of the receiving parts 50-1 and 50-2 is simply referred to as a receiving part 50. Details of a structure of the receiving part 50 will be described later. In addition, in the following description, a side on which the receiving part 50-1 out of the two parts, the receiving parts 50-1 and 50-2, is provided, is referred to as one end side in the X direction. A side on which the receiving part 50-2 out of the two parts, the receiving parts 50-1 and 50-2, is provided, is referred to as the other end side in the X direction.

In addition, the housing 10 further includes connection parts 13 and 14. The connection parts 13 and 14 are made of, for example, a conductor containing metal. The connection part 13 is provided to electrically connect the semiconductor part 40 and the terminal T1. The connection part 14 is provided to electrically connect the semiconductor part 40 and the terminal T2. Note that FIG. 2 illustrates only a part of a structure of each of the connection parts 13 and 14.

The cover 20 further includes engaging parts 60-1 and 60-2. The engaging parts 60-1 and 60-2 are provided so as to correspond to the receiving parts 50-1 and 50-2 of the housing 10, respectively. The engaging parts 60-1 and 60-2 are made of, for example, a synthetic resin. The synthetic resin includes, for example, polyamide. When the engaging parts 60-1 and 60-2 are fitted to the receiving parts 50-1 and 50-2, respectively, the cover 20 is fixed to the housing 10. In the following description, when the engaging parts 60-1 and 60-2 are not distinguished from each other, each of the engaging parts 60-1 and 60-2 is simply referred to as an engaging part 60. Details of a structure of the engaging part 60 will be described later.

In addition, the cover 20 further includes, for example, a connection part 21. The connection part 21 is made of, for example, a conductor containing metal. The connection part 21 is electrically connected to the terminal T3 in a region that is not illustrated. The connection part 21 is provided to electrically connect the semiconductor part 40 and the terminal T3.

The cover 30 is fixed to the housing 10 by, for example, an adhesive member that is not illustrated. In addition, although not illustrated, the cover 30 may include the engaging part for fixing the cover 30 to the housing 10, similarly to the cover 20. In this case, the housing 10 further includes the receiving part corresponding to the engaging part of the cover 30.

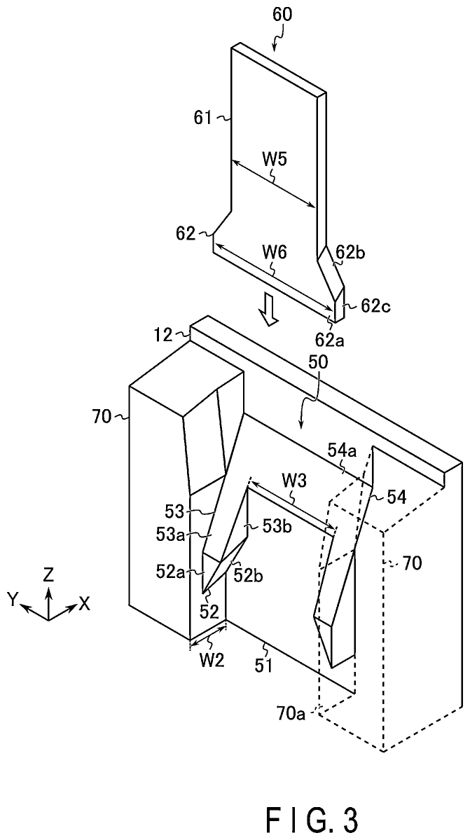

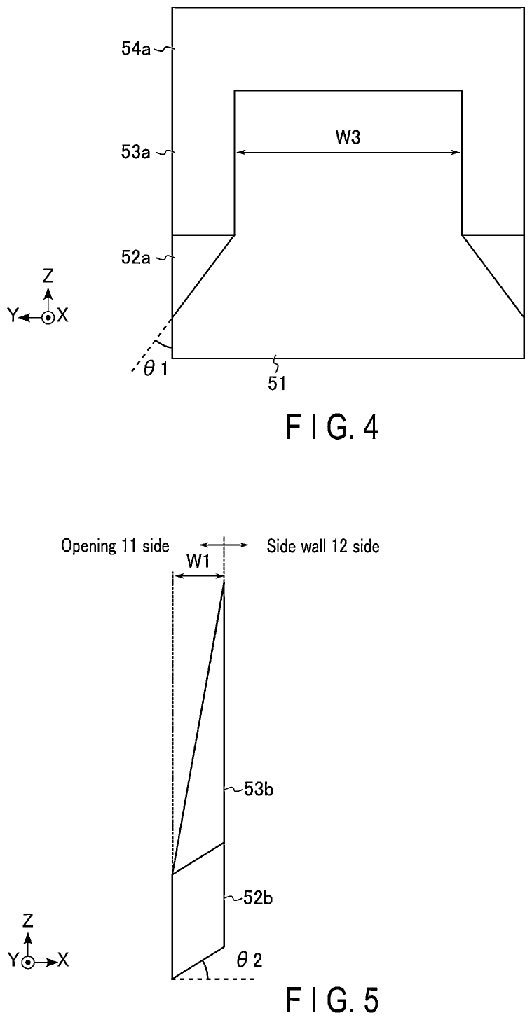

Next, the structure of the receiving part 50 according to the embodiment will be described. The receiving parts 50-1 and 50-2 are provided symmetrically with respect to a YZ plane, for example. Therefore, hereinafter, the structure of the receiving part 50-1 will be described with reference to FIGS. 3, 4, and 5, and the description of the structure of the receiving part 50-2 will be omitted. FIG. 3 is a perspective view illustrating examples of the structures of the receiving part and engaging part of the semiconductor device according to the embodiment. FIG. 4 is a plan view illustrating an example of a structure of the receiving part of the semiconductor device according to the embodiment as viewed from the X direction. FIG. 5 is a plan view illustrating an example of a structure of a portion included in the receiving part 50 of the semiconductor device according to the embodiment as viewed from the Y direction. More specifically, FIG. 4 illustrates a structure when the receiving part 50-1 according to the embodiment is viewed from the other end side toward the one end side in the X direction. In addition, FIG. 5 illustrates a structure when a portion of the receiving part 50-1 according to the embodiment included in the one end side in the Y direction is viewed from the other end side toward the one end side in the Y direction.

The receiving part 50 is provided so as to protrude in the X direction from the side wall 12 toward the opening 11. In addition, the side wall 12 is provided with two guide portions 70 protruding in the X direction from the side wall 12 toward the opening 11. The receiving part 50 is sandwiched between the two guide portions 70 in the Y direction. More specifically, the receiving part 50 is sandwiched between side surfaces of the two guide portions 70 on the one end side and the other end side in the Y direction facing each other in the Y direction. Note that, in FIG. 3, the guide portion 70 on the other end side in the Y direction out of the two guide portions 70 is indicated by a dotted line.

The receiving part 50 includes a wall portion 51, two protruding portions 52, two first sloped portions 53, and a second sloped portion 54. Note that, in FIG. 5, illustrations of the wall portion 51 and the second sloped portion 54 are omitted.

The wall portion 51 has, for example, a flat surface along the YZ plane. The flat surface is in contact with the side surfaces of the one end and the other end of the guide portion 70 in the Y direction.

The protruding portion 52 on the one end side in the Y direction out of the two protruding portions 52, is in contact with, for example, the side surface of the guide portion 70 on the one end side in the Y direction. The protruding portion 52 on the other end side in the Y direction out of the two protruding portions 52, is in contact with, for example, the side surface of the guide portion 70 on the other end side in the Y direction. The protruding portion 52 is provided, for example, so as to protrude from the wall portion 51. As illustrated in FIG. 5, the protruding portion 52 has a thickness W1 in the X direction. The thickness W1 is, for example, 1 mm or more. In addition, the thickness W1 is smaller than a thickness W2 of a portion of the guide portion 70 included in the other end side in the X direction away from the wall portion 51 illustrated in FIG. 3. Note that the two protruding portions 52 are provided symmetrically with respect to an XZ plane. Therefore, hereinafter, a structure of the protruding portion 52 on the one end side in the Y direction will be mainly described, and the description of a structure of the protruding portion 52 on the other end side in the Y direction will be omitted.

The protruding portion 52 has protruding surfaces 52a and 52b. The protruding surface 52a has, for example, a flat surface along the YZ plane. As illustrated in FIG. 4, the protruding surface 52a has, for example, a triangular shape having a side along the Y direction, a side along the Z direction connected to the side surface of the guide portion 70, and an oblique side intersecting the Y direction and the Z direction. On the protruding surface 52a, an angle sandwiched between the side along the Z direction and the oblique side has an angle θ1 as illustrated in FIG. 4. The angle θ1 is, for example, smaller than 90°. With the above configuration, the two protruding portions 52 in the receiving part 50 are provided such that the width of a region sandwiched between the two protruding portions 52 increases from the upper side toward the lower side. The protruding surface 52b has, for example, a flat surface inclined with respect to the Y direction. As illustrated in FIG. 5, the protruding surface 52b has, for example, a quadrangular shape, as viewed from the Y direction, having two sides along the Z direction, and an upper side and a lower side each intersecting with the Z direction, in which the upper side and the lower side become higher from the other end side toward the one end side in the X direction. More specifically, the protruding surface 52b has, for example, a parallelogram shape. An acute angle θ2 formed by the lower side of the protruding surface 52b and the X direction is, for example, 5° or more and 20° or less (5≤θ2 20). The protruding surface 52b is a surface roughened by a mechanical polishing treatment on the surface, a chemical treatment using a chemical on the surface, a treatment on a surface portion of an inner surface of a mold corresponding to the surface when the receiving part 50 is molded, or the like. As a result, the surface roughness (Ra) of the protruding surface 52b is set to, for example, 10 μm (micrometer) or more. In addition, the protruding surface 52b is rougher (has larger surface roughness) than the other surfaces included in the receiving part 50.

The two first sloped portions 53 are provided so as to correspond to the two protruding portions 52. Each of first sloped portions 53 is connected to an upper end of the corresponding one protruding portion 52 out of the two protruding portions 52. The first sloped portion 53 on the one end side in the Y direction out of the two first sloped portions 53, is in contact with, for example, the side surface of the guide portion 70 on the one end side in the Y direction. The first sloped portion 53 on the other end side in the Y direction out of the two first sloped portions 53, is in contact with, for example, the side surface of the guide portion 70 on the other end side in the Y direction. Each of the two first sloped portions 53 is provided, for example, so as to protrude from the wall portion 51. The two first sloped portions 53 are provided such that a region sandwiched between the two first sloped portions 53 is separated by an interval W3 in the Y direction. The interval W3 is, for example, about 10 mm. Note that the two first sloped portions 53 are provided symmetrically with respect to the XZ plane. Therefore, hereinafter, a structure of the first sloped portion 53 on the one end side in the Y direction will be mainly described, and the description of a structure of the first sloped portion 53 on the other end side in the Y direction will be omitted.

The first sloped portion 53 has sloped surfaces 53a and 53b. As illustrated in FIG. 4, the sloped surface 53a has, for example, a rectangular shape. As illustrated in FIG. 5, the sloped surface 53a has, for example, a flat surface along a surface obtained by rotating the YZ plane by a preset angle with respect to the Y direction. More specifically, the sloped surface 53a is inclined so as to become closer to the side wall 12 from the lower side toward the upper side. The sloped surface 53a is connected to the upper end of the protruding surface 52a at the lower end, for example. In addition, the sloped surface 53a is connected to the side surface of the guide portion 70 on the one end side in the Y direction. The sloped surface 53b has, for example, a flat surface along the XZ plane. The sloped surface 53b has, for example, a triangular shape. The sloped surface 53b is connected to the upper end of the protruding surface 52b at the lower end.

The second sloped portion 54 has a sloped surface 54a. The sloped surface 54a has, for example, a flat surface along a surface obtained by rotating the YZ plane by a preset angle with respect to the Y direction. When the YZ plane is used as a reference, the rotation angle of the sloped surface 54a with respect to the Y direction and the rotation angle of the sloped surface 53a with respect to the Y direction are, for example, equal. The lower end of the sloped surface 54a is connected to each of the upper ends of the sloped surface 53a at the one end and the other end along the Y direction. The sloped surface 54a has, for example, a rectangular shape. With the above configuration, the sloped surface 54a is provided integrally with the two sloped surfaces 53a. For example, in the X direction, the second sloped portion 54 is provided closer to the one end in the X direction than the two protruding portions 52 and the two first sloped portion 53, similarly to the wall portion 51. In addition, the sloped surface 54a is connected to each of the side surfaces of the two guide portions 70 on the one end side and the other end side in the Y direction.

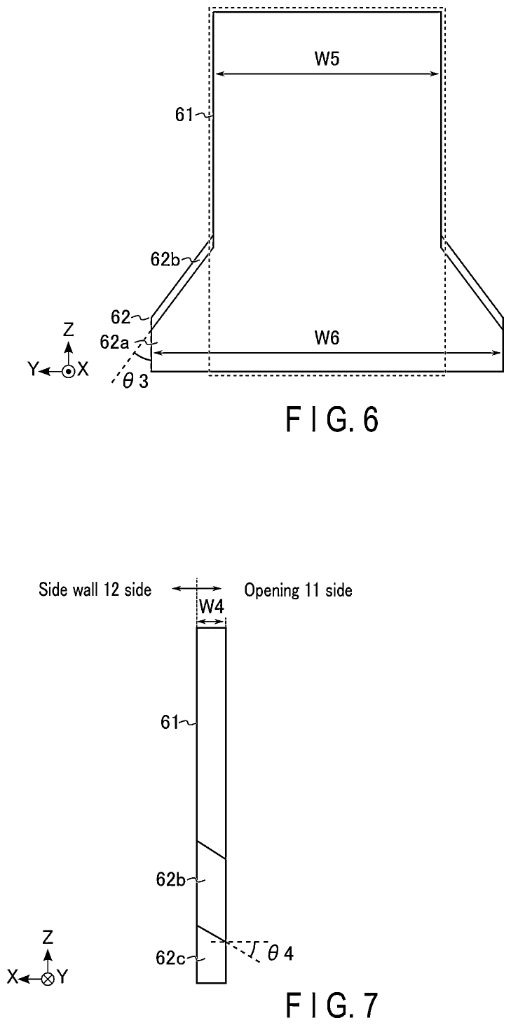

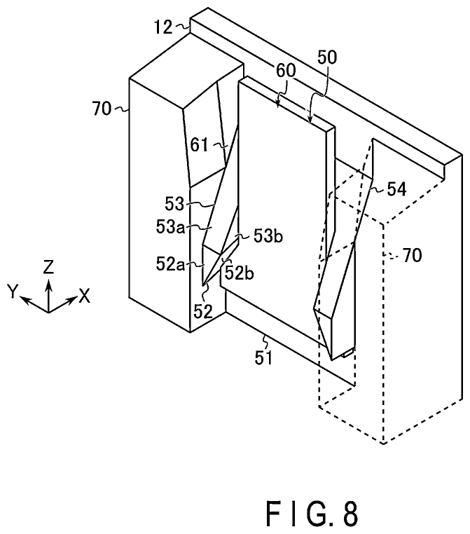

Next, the engaging part 60 according to the embodiment will be described. Note that the engaging parts 60-1 and 60-2 are provided symmetrically with respect to the YZ plane, for example. Therefore, hereinafter, the structure of the engaging part 60-1 will be described with reference to FIGS. 3, 6, and 7, and the description of the structure of the engaging part 60-2 will be omitted. FIG. 6 is a plan view illustrating an example of a structure of the engaging part of the semiconductor device 1 according to the embodiment as viewed from the X direction. FIG. 7 is a plan view illustrating an example of a structure of the engaging part of the semiconductor device according to the embodiment as viewed from the Y direction. More specifically, FIG. 6 illustrates a structure when the engaging part 60-1 according to the embodiment is viewed from the other end side toward the one end side in the X direction. In addition, FIG. 7 illustrates a structure when the engaging part 60-1 according to the embodiment is viewed from the one end side toward the other end side in the Y direction.

The engaging part 60 has a plate-like structure having a flat surface along the YZ plane. As illustrated in FIG. 7, the engaging part 60 has a thickness W4 in the X direction. The thickness W4 is, for example, equal to or less than the thickness W1. The thickness W4 is, for example, about 1 mm.

The engaging part 60 includes an extending portion 61 and a pair of engaging claws 62. The structure of the engaging part 60 is, for example, symmetrical with respect to the XZ plane.

As illustrated in FIG. 6, the extending portion 61 has a rectangular shape as viewed from the X direction. The extending portion 61 is a portion surrounded by a dotted line in FIG. 6. A width W5 of the extending portion 61 in the Y direction is equal to or less than the interval W3.

The engaging claws 62 are provided so as to symmetrically protrude from the extending portion 61 at the one end and the other end in the Y direction. With such a configuration, the engaging part 60 has a spatula-like shape symmetrical with respect to the XZ plane. Therefore, a width W6 of a lower side of the engaging part 60 in the Y direction in a portion including the two engaging claws 62 is wider than the interval W3 and the width W5. With the structure of the symmetrical engaging claws 62 as described above, the structure of the engaging claw 62 on the one end side in the Y direction will be mainly described below, and the description of the structure of the engaging claw 62 on the other end side in the Y direction will be omitted.

The engaging claw 62 has, for example, an engaging surface 62a along the YZ plane and engaging surfaces 62b and 62c intersecting the YZ plane.

The engaging surface 62a has a trapezoidal shape including two sides along the Z direction, a side along the Y direction, and an oblique side intersecting the Y direction and the Z direction. The engaging surface 62a on the one end side in the Y direction is provided such that the width in the Z direction decreases from the other end side in the Y direction toward the one end side. An angle θ3 of an angle formed by the oblique side of the engaging surface 62a and a boundary line between the engaging claw 62 and the extending portion 61 along the Z direction is, for example, equal to the angle θ1.

The engaging surface 62b is connected to a side surface of the extending portion 61 along the XZ plane. In addition, since the oblique side of the engaging surface 62a is inclined as described above, the engaging surface 62b has a flat surface inclined with respect to the Y direction similarly to the protruding surface 52b. As illustrated in FIG. 7, the engaging surface 62b has, for example, a quadrangular shape having two sides along the Z direction, and an upper side and a lower side each intersecting with the Z direction, in which the upper side and the lower side become higher from the other end side toward the one end side in the X direction. More specifically, the engaging surface 62b has, for example, a parallelogram shape. An angle θ4 formed by the lower side of the engaging surface 62b and the X direction is larger than 0°. The angle θ4 is, for example, 5° or more and 20° or less (5≤θ4≤20). In addition, the angle θ4 is, for example, equal to the angle θ2. The engaging surface 62b is a surface roughened by a mechanical polishing treatment on the surface, a chemical treatment using a chemical on the surface, a treatment on a portion of an inner surface of a mold corresponding to the surface when the engaging part 60 is molded, or the like. As a result, the surface roughness (Ra) of the engaging surface 62b is set to, for example, 10 μm or more. In addition, the engaging surface 62b is rougher (has larger surface roughness) than the other surfaces included in the engaging part 60. Furthermore, as illustrated in FIG. 7, the engaging surface 62c has, for example, a quadrangular shape having two sides along the Z direction, a side along the X direction, and a side intersecting the X direction and the Z direction.

Next, a structure in which the engaging part 60 is fixed to the receiving part 50 in the semiconductor device 1 according to the embodiment will be described with reference to FIG. 8. FIG. 8 is a perspective view illustrating examples of the structures of the receiving part and engaging part of the semiconductor device according to the embodiment.

In the semiconductor device 1 according to the embodiment, the engaging part 60 is fixed to the receiving part 50 when the engaging part 60 is slid downward. More specifically, as the engaging part 60 slides downward, the engaging part 60 deforms along the protruding surface 52a, the sloped surface 53a, and the flat surface of the second sloped portion 54. Then, for example, when the engaging claw 62 is further slid downward so as to be positioned below the first sloped portion 53, the engaging part 60 returns to its original shape. At the same time, a portion of the engaging part 60 is disposed between the two protruding portions 52 and the two first sloped portions 53.

With the configuration of the receiving part 50 and the engaging part 60 as described above, when the engaging part 60 is fitted to the receiving part 50, the engaging surface 62b may be entirely in contact with the protruding surface 52b.

According to the embodiment, the reliability of the semiconductor device can be improved. The improvement in reliability by the semiconductor device 1 according to the embodiment will be described below.

The semiconductor device 1 according to the embodiment includes the housing 10 having the opening 11 for housing the semiconductor part 40 and the receiving part 50 provided so as to protrude from the side wall 12 and to which the engaging part 60 is fitted, and the cover 20 having the engaging part 60 extending in the Z direction. The engaging part 60 includes the extending portion 61 and the pair of engaging claws 62 protruding in the Y direction from the extending portion 61 at the lower end of the extending portion 61. Each engaging claw 62 has the engaging surface 62b that is continuous with the side surface of the extending portion 61 and inclined with respect to the Z direction. The receiving part 50 includes the protruding portion 52 having the protruding surface 52b that is provided so as to face the engaging surface 62b and inclined with respect to the Z direction. In addition, the lower side of the engaging surface 62b and the lower side of the protruding surface 52b are inclined so as to become higher toward the side wall along the X direction. With such a configuration, when the engaging part 60 is fixed to the receiving part 50, it is possible to suppress the disengagement of the engaging part 60 from the receiving part 50 due to misalignment of the engaging surface 62b to the opening 11 side. Therefore, the cover 20 of the semiconductor device 1 is suppressed from coming off, thereby improving the reliability of the semiconductor device 1.

To supplement, when the protruding surface of the receiving part has a rectangular shape including a lower side along the X direction as viewed from the Y direction, the engaging surface of the engaging part in contact with the protruding surface also has, for example, a rectangular shape including a lower side along the X direction as viewed from the Y direction. In such a case, due to application of a force to the cover, positional displacement of the receiving part and the engaging part when the engaging part is fixed to the receiving part, and the like, a state of balance of forces acting on the engaging part and the receiving part may be lost, which may cause the engaging surface to be misaligned to the opening side of the housing. As a result, the engaging part may be disengaged from the receiving part. For this reason, the cover of the semiconductor device may come off, for example, even when a force that physically breaks the engaging part is not applied.

According to the embodiment, each of the protruding surface 52b of the receiving part 50 and the engaging surface 62b of the engaging part 60 has, for example, a parallelogram shape having two sides along the Z direction as viewed from the Y direction. In addition, each of the lower sides of the protruding surface 52b and the engaging surface 62b is configured to be higher toward the side wall 12 as viewed in the Y direction. With such a configuration, when the engaging part 60 is fixed to the receiving part 50, the engaging part 60 is suppressed from being disengaged from the receiving part 50, for example, even if a state of balance between the support force of the receiving part 50 and the tensile force of the engaging part 60 is lost.

In addition, the protruding surface 52b and the engaging surface 62b are roughened surfaces. As a result, it is possible to suppress a decrease in the friction coefficient of the protruding surface 52b and the engaging surface 62b and to improve the frictional force acting between the protruding surface 52b and the engaging surface 62b. Therefore, since the anchor effect is exerted, it is possible to suppress the disengagement of the engaging part 60 from the receiving part 50.

The angle θ2 of the angle formed by the lower side of the protruding surface 52b and the X direction and the angle θ4 of the angle formed by the lower side of the engaging surface 62b and the X direction are equal to each other. As a result, the engaging surface 62b may be entirely in contact with the protruding surface 52b. Therefore, the frictional force acting between the protruding surface 52b and the engaging surface 62b can be effectively improved.

In addition, in the semiconductor device 1 according to the embodiment, the angles θ2 and 04 are each 5° or more and 20° or less. When the angles θ2 and 04 are 5° or more, the engaging part 60 is effectively suppressed from being engaged from the receiving part 50. In addition, when the angles θ2 and 04 are 20° or less, destruction of the receiving part 50 and the engaging part 60 due to a decrease in strength or the like is effectively suppressed.

### 2. Modification

Next, a semiconductor device according to a modification will be described. Hereinafter, description of configurations equivalent to those of the embodiment will be omitted, and configurations different from those of the embodiment will be mainly described.

The above-described embodiment describes the case where the engaging claw 62 of the engaging part 60 includes one engaging surface 62b and one engaging surface 62c as viewed from the Y direction, but the present invention is not limited thereto. The engaging claw 62 of the engaging part 60 may include two engaging surfaces 62b as viewed from the Y direction.

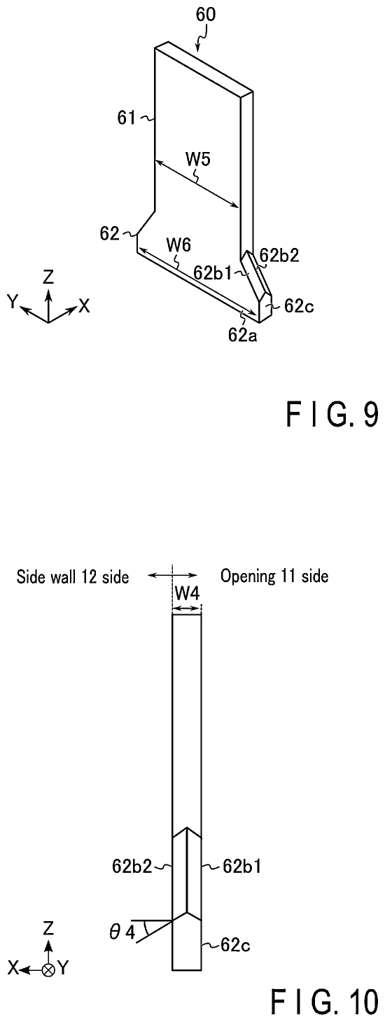

In a semiconductor device 1 according to the modification, configurations of a housing 10 including a receiving part 50, a terminal T3 and a connection part 21 in a cover 20, and a cover 30 are the same as those of the embodiment. Hereinafter, a structure of an engaging part 60 included in the semiconductor device 1 according to the modification will be described with reference to FIGS. 9 and 10 regarding a configuration different from the structure of the engaging part 60 included in the semiconductor device 1 according to the embodiment. FIG. 9 is a perspective view illustrating an example of a structure of the engaging part of the semiconductor device according to the modification as viewed from the X direction. FIG. 10 is a plan view illustrating an example of the structure of the engaging part of the semiconductor device according to the modification as viewed from the Y direction. More specifically, FIG. 10 illustrates a structure when an engaging part 60-1 according to the modification is viewed from the one end side toward the other end side in the Y direction. Note that the structure of the engaging part of the semiconductor device according to the modification as viewed from the X direction can be substantially the same as the structure of the engaging part of the semiconductor device according to the embodiment as viewed from the X direction described with reference to FIG. 6, and thus the description thereof will be omitted.

A structure of an extending portion 61 of an engaging part 60 according to the modification is substantially the same as the structure of the extending portion 61 of the engaging part 60 according to the embodiment.

In the modification, an engaging claw 62 has engaging surfaces 62b1, 62b2, and 62c intersecting the YZ plane. The engaging surfaces 62b1 and 62b2 are surfaces roughened by a mechanical polishing treatment on these surfaces, a chemical treatment using a chemical on these surfaces, a treatment on a portion of an inner surface of a mold corresponding to these surfaces when the engaging part 60 is molded, or the like. As a result, the surface roughness (Ra) of the engaging surfaces 62b1 and 62b2 is set to, for example, 10 μm or more. In addition, the engaging surfaces 62b1 and 62b2 are rougher (has larger surface roughness) than the other surfaces included in the engaging part 60. The engaging surface 62b1 is provided so as to correspond to a protruding surface 52b. As illustrated in FIG. 10, the engaging surface 62b1 has, for example, a quadrangular shape having two sides along the Z direction, and an upper side and a lower side each intersecting with the Z direction, in which the upper side and the lower side become higher from the other end side toward the one end side in the X direction. More specifically, the engaging surface 62b1 has, for example, a parallelogram shape. An angle formed by the lower side of the engaging surface 62b1 and the X direction has an angle θ4. As illustrated in FIG. 10, the engaging surface 62b2 is provided symmetrically with the engaging surface 62b1 with respect to the YZ plane. Due to the configuration of the engaging surfaces 62b1 and 62b2 as described above, the engaging surface 62c has, for example, a pentagonal shape including a side along the X direction, two sides along the Z direction, and two sides intersecting the X direction and the Z direction.

According to the modification, similarly to the embodiment, the reliability of the semiconductor device 1 can be improved.

In addition, according to the modification, the engaging surfaces 62b1 and 62b2 are provided symmetrically with respect to the YZ plane, thus improving versatility. That is, for example, the cover 20 can be manufactured without distinguishing the directions of the engaging parts 60-1 and 60-2.

### 3. Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a housing comprising a side wall surrounding an opening for housing an electronic component, and a receiving part provided so as to protrude from the side wall toward the opening; and
a cover comprising an engaging part extending in a first direction and fitted to the receiving part, and covering at least a portion of the opening, wherein
the engaging part includes an extending portion extending in the first direction and a pair of engaging claws protruding from the extending portion to each of one end side and another end side in a second direction orthogonal to the first direction at a lower end of the extending portion,
each of the engaging claws has a first engaging surface that is continuous with a side surface of the extending portion intersecting the first direction and inclined with respect to the first direction,
the receiving part includes a pair of protruding portions including a protruding surface provided so as to face each of the first engaging surfaces and inclined with respect to the first direction, and
a lower side of the first engaging surface and a lower side of the protruding surface are inclined so as to become higher toward the side wall in a third direction orthogonal to the first direction and the second direction.

2. The semiconductor device according to claim 1, wherein
the lower side of the first engaging surface and the lower side of the protruding surface are inclined by 5° or more and 20° or less with respect to the third direction.

3. The semiconductor device according to claim 1, wherein
the first engaging surface and the protruding surface are a roughened surface.

4. The semiconductor device according to claim 3, wherein
a surface roughness of the first engaging surface and a surface roughness of the protruding surface are 10 micrometers or more.

5. The semiconductor device according to claim 1, wherein
the engaging claw further has a second engaging surface that is continuous with a side surface of the extending portion and inclined with respect to the first direction, and
a lower side of the second engaging surface is inclined with respect to the third direction so as to become higher as the lower side separates from the side wall.

6. The semiconductor device according to claim 5, wherein
the engaging part is symmetrical with respect to a plane including the first direction and the second direction.

7. The semiconductor device according to claim 1, wherein
the engaging part is symmetrical with respect to a plane including the first direction and the third direction.

8. The semiconductor device according to claim 1, wherein
the electronic component is a power semiconductor.

9. A semiconductor device comprising:
a housing comprising a side wall surrounding an opening for housing an electronic component, and a receiving part provided so as to protrude from the side wall toward the opening; and
a cover comprising an engaging part extending in a first direction and fitted to the receiving part, and covering at least a portion of the opening, wherein
the engaging part includes an extending portion extending in the first direction and a pair of engaging claws protruding from the extending portion to each of one end side and another end side in a second direction orthogonal to the first direction at a lower end of the extending portion,
each of the engaging claws has an engaging surface that is continuous with a side surface of the extending portion intersecting the first direction and inclined with respect to the first direction,
the receiving part includes a pair of protruding portions including a protruding surface provided so as to face each of the engaging surfaces and inclined with respect to the first direction, and
the engaging surface and the protruding surface are a roughened surface.

10. The semiconductor device according to claim 9, wherein
a surface roughness of the engaging surface and a surface roughness of the protruding surface are 10 micrometers or more.
